(19) United States
(12) Patent Application Publication
(10) Pub. No.: US 2025/0351375 A1
(43) Pub. Date: Nov. 13, 2025

(54) SEMICONDUCTOR STRUCTURE AND MANUFACTURING METHOD THEREOF

(71) Applicant: United Microelectronics Corp., Hsinchu (TW)

(72) Inventors: Jia-Rong Wu, Kaohsiung City (TW); Rai-Min Huang, Taipei City (TW); I-Fan Chang, Tainan City (TW); Po Kai Hsu, Tainan City (TW); Hui-Lin Wang, Taipei City (TW); Ching Hua Hsu, Kaohsiung City (TW); Che Wei Chang, Taichung City (TW); Chen-Yi Weng, New Taipei City (TW)

(73) Assignee: United Microelectronics Corp., Hsinchu (TW)

(21) Appl. No.: 18/751,348

(22) Filed: Jun. 24, 2024

(30) Foreign Application Priority Data
May 13, 2024 (TW) 113117570

(51) Int. Cl. H10B 61/00

(52) U.S. Cl. CPC H10B 61/00

(57) ABSTRACT

Provided are a semiconductor structure and a manufacturing method thereof. The semiconductor structure includes a substrate, a memory device and a dielectric layer. The substrate has a memory device region and a peripheral region surrounding the memory device region. The memory device is disposed on the substrate in the memory device region. The dielectric layer is disposed on the substrate and covers the memory device. The dielectric layer located in the memory device region includes a ring portion and an auxiliary portion. The ring portion and the auxiliary portion are located at the top of the dielectric layer. The ring portion is adjacent to the boundary between the memory device region and the peripheral region. The auxiliary portion is located in a region surrounded by the ring portion and adjacent to the ring portion.

### CROSS-REFERENCE TO RELATED APPLICATION

This application claims the priority benefit of Taiwan application serial no. 113117570, filed on May 13, 2024. The entirety of the above-mentioned patent application is hereby incorporated by reference herein and made a part of this specification.

### BACKGROUND

### Technical Field

The present invention relates to a semiconductor structure and a manufacturing method thereof, and in particular to a semiconductor structure and a manufacturing method thereof that may avoid the dielectric layer in the memory device region from generating the unnecessary recess or trench at the boundary between the memory device region and the peripheral region after the chemical mechanical polishing (CMP) process.

### Description of Related Art

In the memory process, the memory device is formed on the substrate in the memory device region and other peripheral devices, such as the logic device, the circuit pattern, etc., are formed on the substrate in the peripheral region. After that, the dielectric layer is formed on the substrate to cover the memory device in the memory device region and the peripheral devices in the peripheral region. Compared with the peripheral devices in the peripheral region, the memory device in the memory device region usually has greater thickness. Therefore, after the dielectric layer is formed, the top surface of the dielectric layer in the memory device region is significantly higher than the top surface of the dielectric layer in the peripheral region.

In the current process, in order to effectively planarize the dielectric layer, the etching-back process is usually performed on the dielectric layer in the memory device region to reduce the thickness of the dielectric layer in the memory device region in advance. In addition, after the etching-back process, in addition to removing the dielectric layer in the memory device region to reduce the thickness, a part of the dielectric layer may be remained at the boundary between the memory device region and the peripheral region to form a dielectric ring as the auxiliary structure for the subsequent CMP process.

However, during the CMP process, the dielectric ring is easily peeled by the stress, resulting in the formation of a recess at the boundary between the memory device region and the peripheral region. As a result, when the circuit pattern is formed on the memory device in the subsequent process, the conductive material used to form the circuit pattern may be filled in the recess, causing a bridge problem. In addition, after the dielectric ring is formed by the etching-back process, a trench is easily formed at the bottom of the dielectric ring due to the etching micro-loading effect. As a result, the residue in subsequent processes is easily remained in the trench.

### SUMMARY

The present invention provides a semiconductor structure and a manufacturing method thereof, wherein the dielectric layer in the memory device region includes a ring portion and an auxiliary portion, the ring portion is adjacent to the boundary between the memory device region and the peripheral region, and the auxiliary portion is located in the region surrounded by the ring portion and adjacent to the ring portion.

The semiconductor structure of the present invention includes a substrate, a memory device and a dielectric layer. The substrate has a memory device region and a peripheral region surrounding the memory device region. The memory device is disposed on the substrate in the memory device region. The dielectric layer is disposed on the substrate and covers the memory device. The dielectric layer located in the memory device region includes a ring portion and an auxiliary portion. The ring portion and the auxiliary portion are located at the top of the dielectric layer. The ring portion is adjacent to a boundary between the memory device region and the peripheral region. The auxiliary portion is located in a region surrounded by the ring portion and adjacent to the ring portion.

In an embodiment of the semiconductor structure of the present invention, a width of the auxiliary portion is greater than 0.1 μm.

In an embodiment of the semiconductor structure of the present invention, a top surface of the ring portion and a top surface of the auxiliary portion are coplanar.

In an embodiment of the semiconductor structure of the present invention, from a top view above the substrate, the auxiliary portion includes a ring pattern, an outer sidewall of the ring pattern extends along an inner sidewall of the ring portion, and a distance between the outer sidewall of the ring pattern and the inner sidewall of the ring portion is greater than 0.05 μm.

In an embodiment of the semiconductor structure of the present invention, from a top view above the substrate, the auxiliary portion includes a plurality of ring patterns, in the plurality of ring patterns, an (N+1)th ring pattern is located in a region surrounded by an Nth ring pattern, N is a positive integer, an outer sidewall of each of the plurality of ring patterns extends along an inner sidewall of the ring portion, and a distance between the outer sidewall of the Nth ring pattern and the inner sidewall of the ring portion is greater than 0.05 μm.

In an embodiment of the semiconductor structure of the present invention, a pitch between the Nth ring pattern and the (N+1)th ring pattern is the same as a pitch between the (N+1)th ring pattern and an (N+2)th ring pattern.

In an embodiment of the semiconductor structure of the present invention, a pitch between the Nth ring pattern and the (N+1)th ring pattern is smaller than a pitch between the (N+1)th ring pattern and an (N+2)th ring pattern.

In an embodiment of the semiconductor structure of the present invention, from a top view above the substrate, the auxiliary portion includes a plurality of strip patterns arranged parallel to each other in a first direction, a distance between one end of each of the plurality of strip patterns and an inner sidewall of the ring portion in a second direction intersecting with the first direction is greater than 0.05 μm, and a distance between an outer sidewall of the outermost strip pattern in the plurality of strip patterns and the inner sidewall of the ring portion in the first direction is greater than 0.05 μm.

In an embodiment of the semiconductor structure of the present invention, the auxiliary portion further includes connection patterns to connect the ends of the plurality of strip patterns.

In an embodiment of the semiconductor structure of the present invention, from a top view above the substrate, the auxiliary portion includes a plurality of patterns arranged in an array manner, and a distance between an outer sidewall of the outermost pattern in the plurality of patterns and an inner sidewall of the ring portion is greater than 0.05 μm.

In an embodiment of the semiconductor structure of the present invention, the memory device includes a magnetic tunnel junction structure.

The manufacturing method of a semiconductor structure of the present invention includes the following steps. A substrate is provided, wherein the substrate has a memory device region and a peripheral region surrounding the memory device region. A memory device is formed on the substrate in the memory device region. A dielectric layer is formed on the substrate to cover the memory device. The dielectric layer located in the memory device region includes a ring portion and an auxiliary portion. The ring portion and the auxiliary portion are located at a top of the dielectric layer. The ring portion is adjacent to a boundary between the memory device region and the peripheral region. The auxiliary portion is located in a region surrounded by the ring portion and adjacent to the ring portion.

In an embodiment of the manufacturing method of the present invention, a method for forming the ring portion and the auxiliary portion includes performing a patterning process on the dielectric layer.

In an embodiment of the manufacturing method of the present invention, a width of the auxiliary portion is greater than 0.1 μm.

In an embodiment of the manufacturing method of the present invention, a top surface of the ring portion and a top surface of the auxiliary portion are coplanar.

In an embodiment of the manufacturing method of the present invention, from a top view above the substrate, the auxiliary portion includes a ring pattern, an outer sidewall of the ring pattern extends along an inner sidewall of the ring portion, and a distance between the outer sidewall of the ring pattern and the inner sidewall of the ring portion is greater than 0.05 μm.

In an embodiment of the manufacturing method of the present invention, from a top view above the substrate, the auxiliary portion includes a plurality of ring patterns, in the plurality of ring patterns, an (N+1)th ring pattern is located in a region surrounded by an Nth ring pattern, N is a positive integer, an outer sidewall of each of the plurality of ring patterns extends along an inner sidewall of the ring portion, and a distance between the outer sidewall of the Nth ring pattern and the inner sidewall of the ring portion is greater than 0.05 μm.

In an embodiment of the manufacturing method of the present invention, a pitch between the Nth ring pattern and the (N+1)th ring pattern is the same as a pitch between the (N+1)th ring pattern and an (N+2)th ring pattern.

In an embodiment of the manufacturing method of the present invention, a pitch between the Nth ring pattern and the (N+1)th ring pattern is smaller than a pitch between the (N+1)th ring pattern and an (N+2)th ring pattern.

In an embodiment of the manufacturing method of the present invention, from a top view above the substrate, the auxiliary portion includes a plurality of strip patterns arranged parallel to each other in a first direction, a distance between one end of each of the plurality of strip patterns and an inner sidewall of the ring portion in a second direction intersecting with the first direction is greater than 0.05 μm, and a distance between an outer sidewall of the outermost strip pattern in the plurality of strip patterns and the inner sidewall of the ring portion in the first direction is greater than 0.05 μm.

In an embodiment of the manufacturing method of the present invention, the auxiliary portion further includes connection patterns to connect the ends of the plurality of strip patterns.

In an embodiment of the manufacturing method of the present invention, from a top view above the substrate, the auxiliary portion includes a plurality of patterns arranged in an array manner, and a distance between an outer sidewall of the outermost pattern in the plurality of patterns and an inner sidewall of the ring portion is greater than 0.05 μm.

In an embodiment of the manufacturing method of the present invention, the memory device includes a magnetic tunnel junction structure.

Based on the above, in the semiconductor structure of the present invention and the manufacturing method thereof, from the top view above the substrate, the outer sidewall of the auxiliary portion is adjacent to the inner sidewall of the ring portion, and the distance between the outer sidewall of the auxiliary portion and the inner sidewall of the ring portion is greater than 0.05 μm, so it may effectively prevent the trench being formed at the bottom of the ring portion due to the etching micro-loading effect when the ring portion and the auxiliary portion are formed by the etching-back process.

In addition, when the CMP process is performed on the semiconductor structure of the present invention to reduce the thickness of the dielectric layer, since the auxiliary portion is adjacent to the ring portion as the auxiliary structure of the CMP process, it may effectively prevent the ring portion from being peeled by the stress, thereby avoiding the formation of a recess at the boundary between the memory device region and the peripheral region.

### BRIEF DESCRIPTION OF THE DRAWINGS

FIGS. 1A to 1C are schematic cross-sectional views of the manufacturing process of the semiconductor structure of the first embodiment of the present invention.

FIG. 2 is a schematic top view of the dielectric layer in FIG. 1C.

FIG. 3 is a schematic top view of the dielectric layer of the semiconductor structure of the second embodiment of the present invention.

FIG. 4 is a schematic top view of the dielectric layer of the semiconductor structure of the third embodiment of the present invention.

FIG. 5 is a schematic top view of the dielectric layer of the semiconductor structure of the fourth embodiment of the present invention.

FIG. 6 is a schematic top view of the dielectric layer of the semiconductor structure of the fifth embodiment of the present invention.

FIG. 7 is a schematic top view of the dielectric layer of the semiconductor structure of the sixth embodiment of the present invention.

### DESCRIPTION OF THE EMBODIMENTS

The embodiments are listed below and described in detail with the accompanying drawings, but the provided embodiments are not intended to limit the scope of the present invention. In addition, the drawings are for illustration purposes only and are not drawn to original scale. In order to facilitate understanding, the same devices will be described with the same symbols in the following descriptions.

In the text, the terms mentioned in the text, such as “comprising”, “including”, “containing” and “having” are all open-ended terms, i.e., meaning “including but not limited to”.

When using terms such as “first” and “second” to describe elements, it is only used to distinguish the elements from each other, and does not limit the order or importance of the devices. Therefore, in some cases, the first element may also be called the second element, the second element may also be called the first element, and this is not beyond the scope of the present invention.

In addition, the directional terms, such as “on”, “above”, “under” and “below” mentioned in the text are only used to refer to the direction of the drawings, and are not used to limit the present invention. Therefore, it should be understood that “on” may be used interchangeably with “under”. When a device such as a layer or a film is placed “on” another device, the device may be placed directly on the other device, or an intermediate device may be present. On the other hand, when a device is placed “directly on” another device, there is no intermediate device between the two.

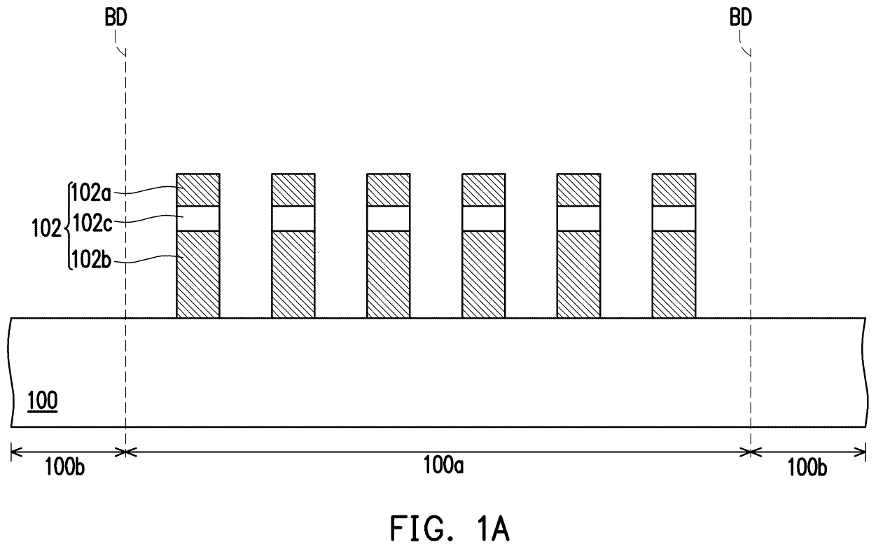

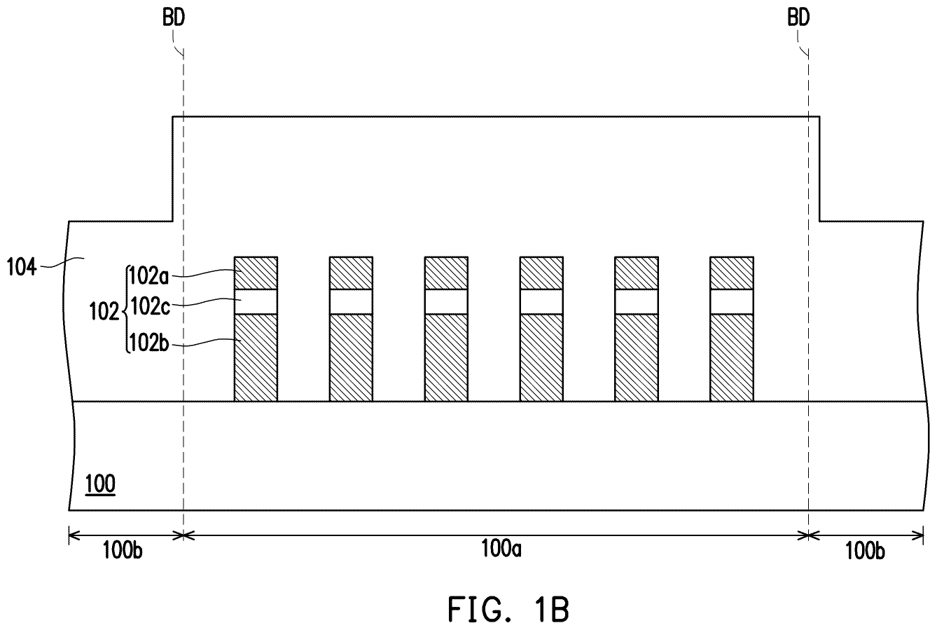

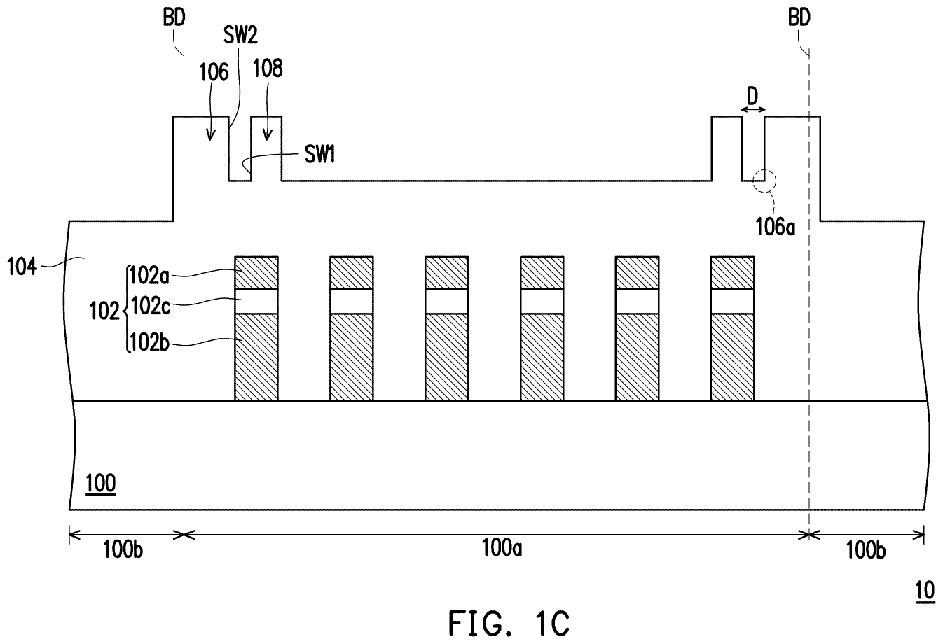

FIGS. 1A to 1C are schematic cross-sectional views of the manufacturing process of the semiconductor structure of the first embodiment of the present invention.

Referring to FIG. 1A, a substrate 100 is provided. In the present embodiment, the substrate 100 may be a silicon substrate, but the present invention is not limited thereto. The substrate 100 has a memory device region 100a and a peripheral region 100b surrounding the memory device region 100a. There is a boundary BD between memory device region 100a and peripheral region 100b. In the present embodiment, the peripheral region 100b may be a region where the device other than the memory device to be formed, and the device other than the memory device may be the logic device, the circuit pattern, etc., but the present invention is not limited thereto.

Next, memory devices 102 are formed on the substrate 100 in the memory device region 100a, and peripheral devices, such as the logic device, circuit pattern, etc., are formed on the substrate 100 in the peripheral region 100b. In FIG. 1A, the peripheral devices are not shown to make the drawing clear, and the peripheral devices are well known to those skilled in the art. In addition, in the present embodiment, the memory device 102 may be a memory device including the MTJ structure, but the present invention is not limited thereto. In other embodiments, the memory device 102 may be any kind of memory device.

For example, in the present embodiment, the memory device 102 includes a top electrode 102a, a bottom electrode 102b and a MTJ structure 102c disposed between the top electrode 102a and the bottom electrode 102b. The memory devices 102 are arranged on the substrate 100 in the memory device region 100a in an array manner. In FIG. 1A, the number of the memory devices 102 is only exemplary, and the present invention does not limit this. Generally speaking, compared with various peripheral devices in the peripheral region 100b, the memory device 102 in the memory device region 100a usually has greater thickness.

Referring to FIG. 1B, a dielectric layer 104 is formed on the substrate 100. The dielectric layer 104 us used as an inter-layer dielectric (ILD) layer. The dielectric layer 104 covers the memory devices 102 in the memory device region 100a and the peripheral devices in the peripheral region 100b. Since the memory device 102 in the memory device region 100a has a greater thickness than the peripheral devices in the peripheral region 100b, after the dielectric layer 104 is formed, the top surface of the dielectric layer 104 in the memory device region 100a may be significantly higher than the top surface of the dielectric layer 104 in the peripheral region 100b.

In the current semiconductor process, in order to effectively planarize a layer with significant height difference, before performing the CMP process for planarization, an etching-back process may be performed on the portion of the layer with greater thickness to reduce the thickness in advance. Further, in the etching-back process, in addition to reducing the thickness of the layer, an auxiliary structure may be formed at the portion with greater thickness for the CMP process. Therefore, in the present embodiment, the above method is used to perform an etching-back process on the dielectric layer 104 and form an auxiliary structure for the CMP process. This will be explained below.

Referring to FIG. 1C, after forming the dielectric layer 104, an etching-back process is performed to pattern the dielectric layer 104 in the memory device region 100a to form a ring portion 106 and an auxiliary portion 108 at the top of the dielectric layer 104 in the memory device region 100a.

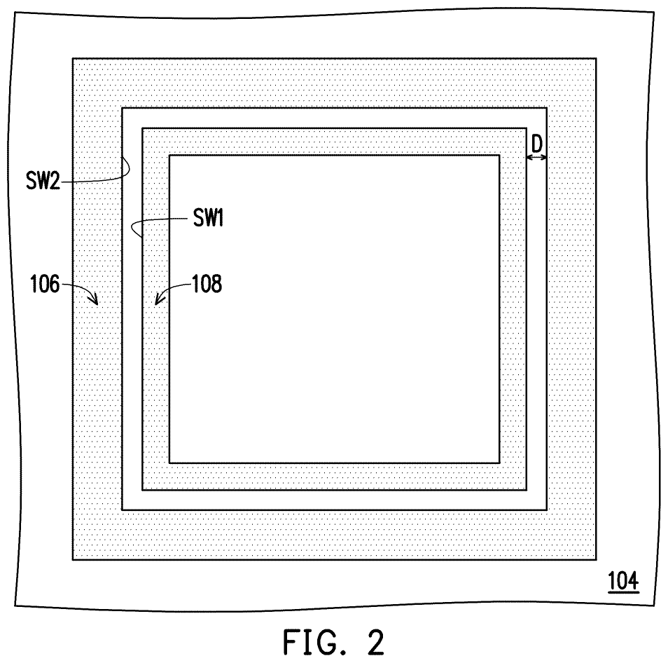

Specifically, in the present embodiment, the etching-back process is performed on the dielectric layer 104 in the memory device region 100a, and a part of the dielectric layer 104 is removed. As shown in FIG. 2, at the top of the dielectric layer 104 in the memory device region 100a, the ring portion 106 adjacent to the boundary BD between the memory device region 100a and the peripheral region 100b is formed, and the auxiliary portion 108 adjacent the ring portion 106 in the region surrounded by the ring portion 106 is formed. The top surface of the ring portion 106 and the top surface of the auxiliary portion 108 may be coplanar. In this way, the semiconductor structure 10 of the present embodiment is formed. In the present embodiment, the width of the auxiliary portion 108 is greater than 0.1 μm, and the distance D between the outer sidewall SW1 of the auxiliary portion 108 and the inner sidewall SW2 of the ring portion 106 is greater than 0.05 μm.

In the present embodiment, as shown in FIG. 2, from the top view above the substrate 100, the auxiliary portion 108 has a ring pattern, and the outer sidewall SW1 of the ring pattern extends along the inner sidewall SW2 of the ring portion 106. Since the outer sidewall SW1 of the auxiliary portion 108 is adjacent to the inner sidewall SW2 of the ring portion 106 and the distance D between the outer sidewall SW1 of the auxiliary portion 108 and the inner sidewall SW2 of the ring portion 106 is greater than 0.05 μm, when the ring portion 106 and the auxiliary portion 108 are formed by the etching-back process, it may effectively prevent the trench being formed at the bottom 106a of the ring portion 106 due to the etching micro-loading effect.

In addition, when the semiconductor structure 10 of the present embodiment is subjected to the CMP process to reduce the thickness of the dielectric layer 104, since the auxiliary portion 108 is adjacent to the ring portion 106 as the auxiliary structure of the CMP process, it may effectively prevent the ring portion 106 from being peeled by the stress, thereby avoiding the formation of the recess at the boundary BD between the memory device region 100a and the peripheral region 100b.

In the present embodiment, the auxiliary portion 108 has a ring pattern, and the outer sidewall of the ring pattern extends along the inner sidewall of the ring portion 106, but the present invention is not limited thereto. In other embodiments, the auxiliary portion 108 may have other configuration.

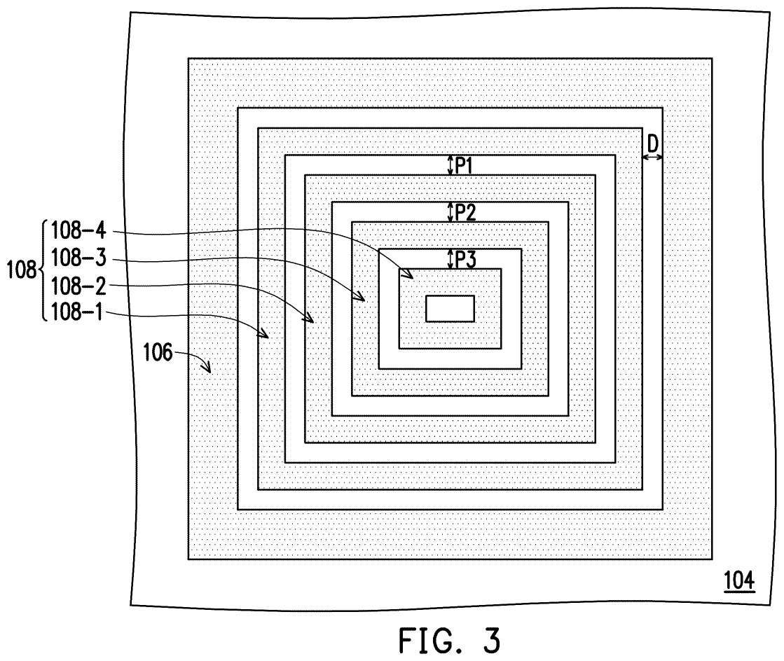

FIG. 3 is a schematic top view of the dielectric layer of the semiconductor structure of the second embodiment of the present invention. In the present embodiment, devices that are the same as those in the first embodiment will be represented by the same reference symbols and will not be described again.

Referring to FIG. 3, after the etching-back process is performed on the dielectric layer 104, at the top of the dielectric layer 104 in the memory device region 100a, the ring portion 106 is formed adjacent to the boundary BD between the memory device region 100a and the peripheral region 100b, and the auxiliary portion 108 including a plurality of ring patterns is formed adjacent to the ring portion 106 in the region surrounded by ring portion 106.

In the present embodiment, from the top view above the substrate 100, the auxiliary portion 108 includes a first ring pattern 108-1, a second ring pattern 108-2, a third ring pattern 108-3 and a fourth ring pattern 108-4. In the auxiliary portion 108, the second ring pattern 108-2 is located in the region surrounded by the first ring pattern 108-1, the third ring pattern 108-3 is located in the region surrounded by the second ring pattern 108-2, and the fourth ring pattern 108-4 is located in the region surrounded by third ring pattern 108-3. In FIG. 3, the number of the ring patterns is only exemplary, and the present invention does not limit this. In other embodiments, the auxiliary portion 108 may include fewer or more ring patterns.

In the auxiliary portion 108, the outer sidewalls of the first ring pattern 108-1, the second ring pattern 108-2, the third ring pattern 108-3 and the fourth ring pattern 108-4 all extend along the inner sidewall of the ring portion 106, and the distance D between the outer sidewall of the outermost first ring pattern 108-1 and the inner sidewall of the ring portion 106 is greater than 0.05 μm.

In addition, in the present embodiment, the pitch P1 between the first ring pattern 108-1 and the second ring pattern 108-2, the pitch P2 between the second ring pattern 108-2 and the third ring pattern 108-3 and the pitch P3 between the third ring pattern 108-3 and the fourth ring pattern 108-4 are equal.

In the present embodiment, in the auxiliary portion 108, since the outer sidewall of the outermost first ring pattern 108-1 is adjacent to the inner sidewall of the ring portion 106 and the distance D between the outer sidewall of the first ring pattern 108-1 and the inner sidewall of the ring portion 106 is greater than 0.05 μm, when the ring portion 106 and the auxiliary portion 108 are formed by the etching-back process, it may effectively prevent the trench being formed at the bottom of the ring portion 106 due to the etching micro-loading effect.

In addition, when the semiconductor structure of the present embodiment is subjected to the CMP process to reduce the thickness of the dielectric layer 104, since the auxiliary portion 108 is adjacent to the ring portion 106 as the auxiliary structure of the CMP process, it may effectively prevent the ring portion 106 from being peeled by the stress, thereby avoiding the formation of the recess at the boundary BD between the memory device region 100a and the peripheral region 100b.

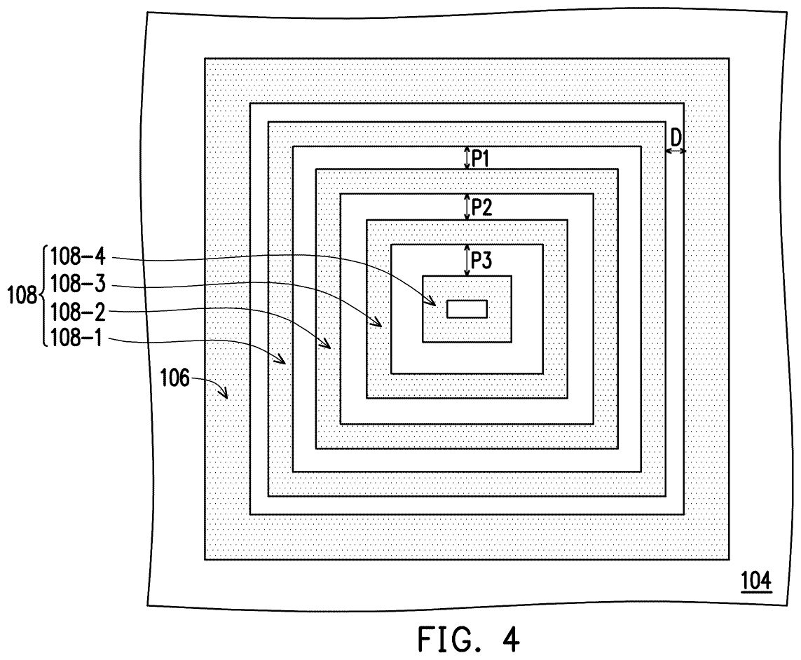

FIG. 4 is a schematic top view of the dielectric layer of the semiconductor structure of the third embodiment of the present invention. In the present embodiment, devices that are the same as those in the second embodiment will be represented by the same reference symbols and will not be described again.

Referring to FIG. 4, the difference between the present embodiment and the second embodiment is that: in the present embodiment, from the top view above the substrate 100, the auxiliary portion 108 includes the first ring pattern 108-1, the second ring pattern 108-2, the third ring pattern 108-3 and the fourth ring pattern 108-4, and the distance between two adjacent ring patterns increases from outside to inside. That is, in the present embodiment, the pitch P1 between the first ring pattern 108-1 and the second ring pattern 108-2 is smaller than the pitch P2 between the second ring pattern 108-2 and the third ring pattern 108-3, the pitch P2 between the second ring pattern 108-2 and the third ring pattern 108-3 is smaller than the pitch P3 between the third ring pattern 108-3 and the fourth ring pattern 108-4.

In the present embodiment, in the auxiliary portion 108, since the outer sidewall of the outermost first ring pattern 108-1 is adjacent to the inner sidewall of the ring portion 106 and the distance D between the outer sidewall of the first ring pattern 108-1 and the inner sidewall of the ring portion 106 is greater than 0.05 μm, when the ring portion 106 and the auxiliary portion 108 are formed by the etching-back process, it may effectively prevent the trench being formed at the bottom of the ring portion 106 due to the etching micro-loading effect.

In addition, when the semiconductor structure of the present embodiment is subjected to the CMP process to reduce the thickness of the dielectric layer 104, since the auxiliary portion 108 is adjacent to the ring portion 106 as the auxiliary structure of the CMP process, it may effectively prevent the ring portion 106 from being peeled by the stress, thereby avoiding the formation of the recess at the boundary BD between the memory device region 100a and the peripheral region 100b.

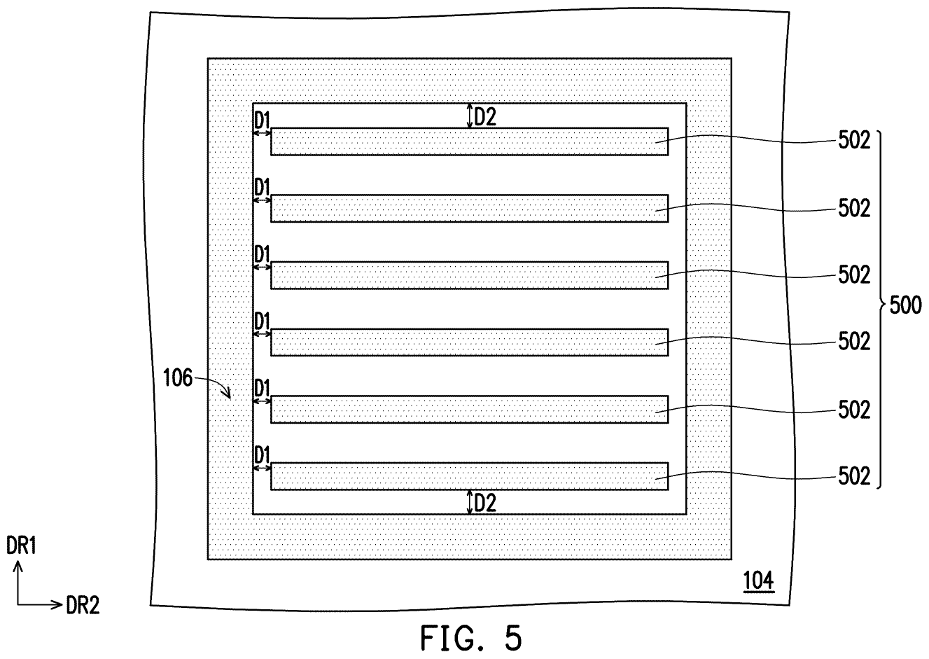

FIG. 5 is a schematic top view of the dielectric layer of the semiconductor structure of the fourth embodiment of the present invention. In the present embodiment, devices that are the same as those in the first embodiment will be represented by the same reference symbols and will not be described again.

Referring to FIG. 5, after the etching-back process is performed on the dielectric layer 104, at the top of the dielectric layer 104 in the memory device region 100a, the ring portion 106 is formed adjacent to the boundary BD between the memory device region 100a and the peripheral region 100b, and in the region surrounded by the ring portion 106, from the top view above the substrate 100, an auxiliary portion 500 including a plurality of strip patterns 502 arranged parallel to each other in a first direction DR1 is formed adjacent to the ring portion 106. In FIG. 5, the number of the strip patterns 502 is only exemplary, and the present invention does not limit this. In other embodiments, the auxiliary portion 500 may include fewer or more strip patterns 502.

In the auxiliary portion 500, the distance D1 between one end of each of the strip patterns 502 and the inner sidewall of the ring portion 106 in a second direction DR2 intersecting with the first direction DR1 is greater than 0.05 μm, and the distance D2 between the outermost strip pattern 205 and the inner sidewall of the ring portion 106 in the first direction DR1 is greater than 0.05 μm.

In the present embodiment, in the auxiliary portion 500, since the distance D1 between one end of each of the strip patterns 502 and the inner sidewall of the ring portion 106 is greater than 0.05 μm, the outer sidewall of the outermost strip pattern 502 is adjacent to the inner sidewall of the ring portion 106, and the distance D2 between the outer sidewall of the outermost strip pattern 502 and the inner sidewall of the ring portion 106 is greater than 0.05 μm, when the ring portion 106 and the auxiliary portion 500 are formed by the etching-back process, it may effectively prevent the trench being formed at the bottom of the ring portion 106 due to the etching micro-loading effect.

In addition, when the semiconductor structure of the present embodiment is subjected to the CMP process to reduce the thickness of the dielectric layer 104, since the auxiliary portion 500 is adjacent to the ring portion 106 as the auxiliary structure of the CMP process, it may effectively prevent the ring portion 106 from being peeled by the stress, thereby avoiding the formation of the recess at the boundary BD between the memory device region 100a and the peripheral region 100b.

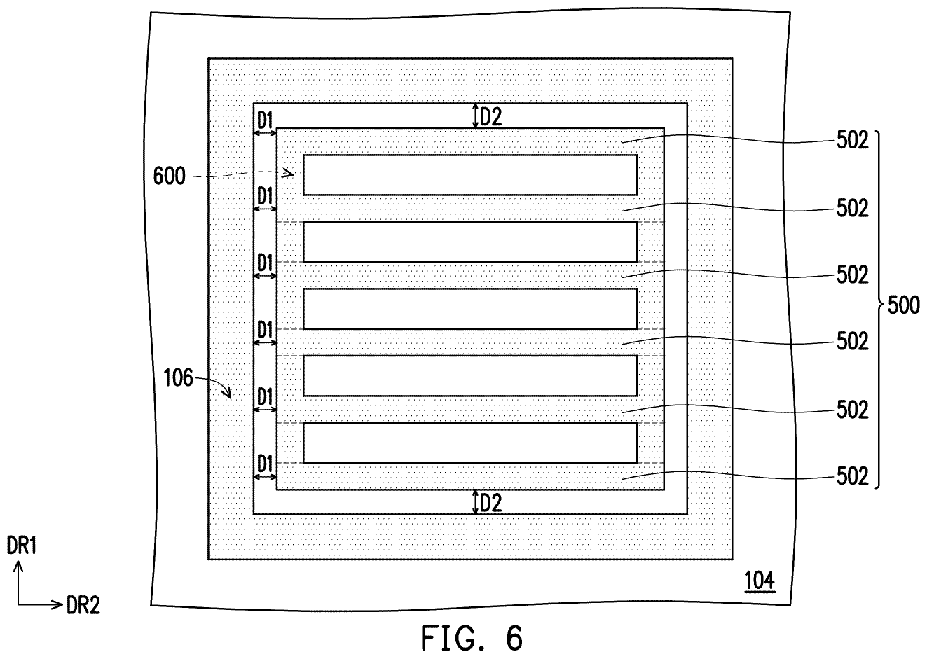

FIG. 6 is a schematic top view of the dielectric layer of the semiconductor structure of the fifth embodiment of the present invention. In the present embodiment, devices that are the same as those in the fourth embodiment will be represented by the same reference symbols and will not be described again.

Referring to FIG. 6, the difference between the present embodiment and the fourth embodiment is that: in the present embodiment, from the top view above the substrate 100, the auxiliary portion 500 includes a plurality of strip patterns 502 arranged parallel to each other in the first direction DR1 and connection patterns 600 formed between two adjacent strip patterns 502 to connect the ends of the two adjacent strip patterns 502. In addition, in the present embodiment, the strip patterns 502 and the connection patterns 600 are integrated.

In the present embodiment, in the auxiliary portion 500, since the distance D1 between one end of each of the strip patterns 502 and the inner sidewall of the ring portion 106 is greater than 0.05 μm, the outer sidewall of the outermost strip pattern 502 is adjacent to the inner sidewall of the ring portion 106, and the distance D2 between the outer sidewall of the outermost strip pattern 502 and the inner sidewall of the ring portion 106 is greater than 0.05 μm, when the ring portion 106 and the auxiliary portion 500 are formed by the etching-back process, it may effectively prevent the trench being formed at the bottom of the ring portion 106 due to the etching micro-loading effect.

In addition, when the semiconductor structure of the present embodiment is subjected to the CMP process to reduce the thickness of the dielectric layer 104, since the auxiliary portion 500 is adjacent to the ring portion 106 as the auxiliary structure of the CMP process, it may effectively prevent the ring portion 106 from being peeled by the stress, thereby avoiding the formation of the recess at the boundary BD between the memory device region 100a and the peripheral region 100b.

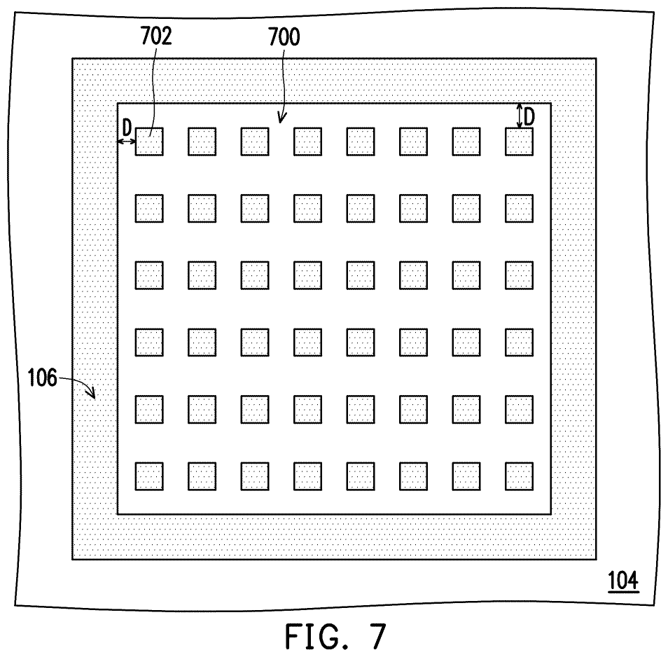

FIG. 7 is a schematic top view of the dielectric layer of the semiconductor structure of the sixth embodiment of the present invention. In the present embodiment, devices that are the same as those in the first embodiment will be represented by the same reference symbols and will not be described again.

Referring to FIG. 7, after the etching-back process is performed on the dielectric layer 104, at the top of the dielectric layer 104 in the memory device region 100a, the ring portion 106 is formed adjacent to the boundary BD between the memory device region 100a and the peripheral region 100b, and in the region surrounded by the ring portion 106, from the top view above the substrate 100, an auxiliary portion 700 including a plurality of patterns 702 arranged in an array manner is formed adjacent to the ring portion 106. In FIG. 7, the number and shape of the patterns 702 are only exemplary, and the present invention does not limit this. In other embodiments, the auxiliary portion 700 may include fewer or more patterns 702, and the patterns 702 may have other shapes.

In the auxiliary portion 700, the distance D between the outer sidewall of the outermost pattern 702 and the inner sidewall of the ring portion 106 is greater than 0.05 μm.

In the present embodiment, in the auxiliary portion 700, since the outer sidewall of the outermost pattern 702 is adjacent to the inner sidewall of the ring portion 106, and the distance D between the outer sidewall of the outermost pattern 702 and the inner sidewall of the ring portion 106 is greater than 0.05 μm, when the ring portion 106 and the auxiliary portion 700 are formed by the etching-back process, it may effectively prevent the trench being formed at the bottom of the ring portion 106 due to the etching micro-loading effect.

In addition, when the semiconductor structure of the present embodiment is subjected to the CMP process to reduce the thickness of the dielectric layer 104, since the auxiliary portion 700 is adjacent to the ring portion 106 as the auxiliary structure of the CMP process, it may effectively prevent the ring portion 106 from being peeled by the stress, thereby avoiding the formation of the recess at the boundary BD between the memory device region 100a and the peripheral region 100b.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor structure, comprising:
a substrate, having a memory device region and a peripheral region surrounding the memory device region;
a memory device, disposed on the substrate in the memory device region; and
a dielectric layer, disposed on the substrate and covering the memory device,
wherein:
the dielectric layer located in the memory device region comprises a ring portion and an auxiliary portion,
the ring portion and the auxiliary portion are located at a top of the dielectric layer,
the ring portion is adjacent to a boundary between the memory device region and the peripheral region, and
the auxiliary portion is located in a region surrounded by the ring portion and adjacent to the ring portion.

2. The semiconductor structure of claim 1, wherein a width of the auxiliary portion is greater than 0.1 μm.

3. The semiconductor structure of claim 1, wherein a top surface of the ring portion and a top surface of the auxiliary portion are coplanar.

4. The semiconductor structure of claim 1, wherein from a top view above the substrate, the auxiliary portion comprises a ring pattern, an outer sidewall of the ring pattern extends along an inner sidewall of the ring portion, and a distance between the outer sidewall of the ring pattern and the inner sidewall of the ring portion is greater than 0.05 μm.

5. The semiconductor structure of claim 1, wherein from a top view above the substrate, the auxiliary portion comprises a plurality of ring patterns, in the plurality of ring patterns, an (N+1)th ring pattern is located in a region surrounded by an Nth ring pattern, N is a positive integer, an outer sidewall of each of the plurality of ring patterns extends along an inner sidewall of the ring portion, and a distance between the outer sidewall of the Nth ring pattern and the inner sidewall of the ring portion is greater than 0.05 μm.

6. The semiconductor structure of claim 5, wherein a pitch between the Nth ring pattern and the (N+1)th ring pattern is the same as a pitch between the (N+1)th ring pattern and an (N+2)th ring pattern.

7. The semiconductor structure of claim 5, wherein a pitch between the Nth ring pattern and the (N+1)th ring pattern is smaller than a pitch between the (N+1)th ring pattern and an (N+2)th ring pattern.

8. The semiconductor structure of claim 1, wherein from a top view above the substrate, the auxiliary portion comprises a plurality of strip patterns arranged parallel to each other in a first direction, a distance between one end of each of the plurality of strip patterns and an inner sidewall of the ring portion in a second direction intersecting with the first direction is greater than 0.05 μm, and a distance between an outer sidewall of the outermost strip pattern in the plurality of strip patterns and the inner sidewall of the ring portion in the first direction is greater than 0.05 μm.

9. The semiconductor structure of claim 8, wherein the auxiliary portion further comprises connection patterns to connect the ends of the plurality of strip patterns.

10. The semiconductor structure of claim 1, wherein from a top view above the substrate, the auxiliary portion comprises a plurality of patterns arranged in an array manner, and a distance between an outer sidewall of the outermost pattern in the plurality of patterns and an inner sidewall of the ring portion is greater than 0.05 μm.

11. The semiconductor structure of claim 1, wherein the memory device comprises a magnetic tunnel junction structure.

12. A manufacturing method of a semiconductor structure, comprising:
providing a substrate, wherein the substrate has a memory device region and a peripheral region surrounding the memory device region;
forming a memory device on the substrate in the memory device region; and
forming a dielectric layer on the substrate to cover the memory device,
wherein:
the dielectric layer located in the memory device region comprises a ring portion and an auxiliary portion,
the ring portion and the auxiliary portion are located at a top of the dielectric layer,
the ring portion is adjacent to a boundary between the memory device region and the peripheral region, and
the auxiliary portion is located in a region surrounded by the ring portion and adjacent to the ring portion.

13. The manufacturing method of claim 12, wherein a method for forming the ring portion and the auxiliary portion comprises performing a patterning process on the dielectric layer.

14. The manufacturing method of claim 12, wherein a width of the auxiliary portion is greater than 0.1 μm.

15. The manufacturing method of claim 12, wherein a top surface of the ring portion and a top surface of the auxiliary portion are coplanar.

16. The manufacturing method of claim 12, wherein from a top view above the substrate, the auxiliary portion comprises a ring pattern, an outer sidewall of the ring pattern extends along an inner sidewall of the ring portion, and a distance between the outer sidewall of the ring pattern and the inner sidewall of the ring portion is greater than 0.05 μm.

17. The manufacturing method of claim 12, wherein from a top view above the substrate, the auxiliary portion comprises a plurality of ring patterns, in the plurality of ring patterns, an (N+1)th ring pattern is located in a region surrounded by an Nth ring pattern, N is a positive integer, an outer sidewall of each of the plurality of ring patterns extends along an inner sidewall of the ring portion, and a distance between the outer sidewall of the Nth ring pattern and the inner sidewall of the ring portion is greater than 0.05 μm.

18. The manufacturing method of claim 17, wherein a pitch between the Nth ring pattern and the (N+1)th ring pattern is the same as a pitch between the (N+1)th ring pattern and an (N+2)th ring pattern.

19. The manufacturing method of claim 17, wherein a pitch between the Nth ring pattern and the (N+1)th ring pattern is smaller than a pitch between the (N+1)th ring pattern and an (N+2)th ring pattern.

20. The manufacturing method of claim 12, wherein from a top view above the substrate, the auxiliary portion comprises a plurality of strip patterns arranged parallel to each other in a first direction, a distance between one end of each of the plurality of strip patterns and an inner sidewall of the ring portion in a second direction intersecting with the first direction is greater than 0.05 μm, and a distance between an outer sidewall of the outermost strip pattern in the plurality of strip patterns and the inner sidewall of the ring portion in the first direction is greater than 0.05 μm.

21. The manufacturing method of claim 20, wherein the auxiliary portion further comprises connection patterns to connect the ends of the plurality of strip patterns.

22. The manufacturing method of claim 12, wherein from a top view above the substrate, the auxiliary portion comprises a plurality of patterns arranged in an array manner, and a distance between an outer sidewall of the outermost pattern in the plurality of patterns and an inner sidewall of the ring portion is greater than 0.05 μm.

23. The manufacturing method of claim 12, wherein the memory device comprises a magnetic tunnel junction structure.
